(19) United States
(12) Patent Application Publication
(10) Pub. No.: US 2025/0096840 A1
(43) Pub. Date: Mar. 20, 2025

(54) Radio-frequency Power Detector with Common Mode Leakage Cancellation

(71) Applicant: Apple Inc., Cupertino, CA (US)

(72) Inventor: Kerim Kibaroglu, Costa Mesa, CA (US)

(21) Appl. No.: 18/649,395

(22) Filed: Apr. 29, 2024

Related U.S. Application Data
(60) Provisional application No. 63/583,544, filed on Sep. 18, 2023.

(51) Int. Cl. H04B 1/525; H03F 1/26; H03F 3/45; H04B 1/00

(52) U.S. Cl. CPC H04B 1/525; H03F 1/26; H03F 3/4565; H04B 1/0082; H03F 2200/294; H03F 2200/451; H03F 2200/541

(57) ABSTRACT

Wireless circuitry can include a radio-frequency amplifier, a mixer configured to receive a local oscillator (LO) signal, and a power detector having an input port coupled to the radio-frequency amplifier and having a separate common mode cancellation input port configured to receive a common mode leakage signal associated with the LO signal. The wireless circuitry can further include a transformer coupled between the radio-frequency amplifier and the mixer. The input port of the power detector may be coupled to a first coil of the transformer. The common mode cancellation input port of the power detector may be coupled to the first coil or to a second coil of the transformer. One or more capacitors can be coupled between the transformer and the common mode cancellation input port of the power detector. Cancelling common mode leakage signals in this way can improve the dynamic range of the power detector.

This application claims the benefit of U.S. Provisional Patent Application No. 63/583,544, filed Sep. 18, 2023, which is hereby incorporated by reference herein in its entirety.

### FIELD

This disclosure relates generally to electronic devices and, more particularly, to electronic devices with wireless communications circuitry.

### BACKGROUND

Electronic devices can be provided with wireless communications capabilities. An electronic device with wireless communications capabilities has wireless communications circuitry with one or more antennas. Wireless transceiver circuitry in the wireless communications circuitry uses the antennas to transmit and receive radio-frequency signals.

Radio-frequency signals transmitted by an antenna can be fed through a power amplifier, which is configured to amplify low power analog signals to higher power signals more suitable for transmission through the air over long distances. Radio-frequency signals received at an antenna can be fed through a low noise amplifier, which is configured to amplify low power analog signals to higher power signals for ease of processing at a receiver. Power detectors can be used to measure the power level of a power amplifier or a low noise amplifier. It can be challenging to design a satisfactory power detector.

### SUMMARY

An electronic device may include wireless communications circuitry. The wireless communications circuitry may include one or more processors or signal processing blocks for generating baseband signals, a transceiver for upconverting (modulating) the baseband signals to radio frequencies and for downconverting (demodulating) radio-frequency signals to baseband signals, a radio-frequency power amplifier for amplifying radio-frequency signals prior to transmission at one or more antennas, and a radio-frequency low noise amplifier for amplifying radio-frequency signals received at one or more antennas in the electronic device.

An aspect of the disclosure provides wireless circuitry that includes a radio-frequency amplifier, a mixer coupled to the radio-frequency (RF) amplifier and configured to receive an oscillating signal, and a power detection circuit having an input port coupled to the radio-frequency amplifier and having a common mode cancellation input port, different than the input port, configured to receive a common mode leakage signal associated with the oscillating signal. The wireless circuitry can further include a transformer having a first coil coupled to the radio-frequency amplifier and having a second coil coupled to the mixer. The input port of the power detection circuit can be coupled to output or input ports of the RF amplifier via a pair of coupling capacitors. The common mode cancellation input port of power detection circuit can be coupled to the input port of the power detection circuit or to the second coil of the transformer via one or more adjustable capacitor(s) or resistor(s). The one or more adjustable capacitor(s) or resistor(s) can be trimmed to fully cancel out or only partially cancel out a common mode leakage signal received at the input port of the power detection circuit.

An aspect of the disclosure provides circuitry that includes a radio-frequency amplifier and a power detection circuit coupled to an output or input port of the radio-frequency amplifier. The power detection circuit can include a first input transistor coupled to the output or input port of the radio-frequency amplifier, a second input transistor coupled to the output or input port of the radio-frequency amplifier, and a replica input transistor coupled to a common mode cancellation input port of the power detection circuit. The circuitry can further include a mixer coupled to the radio-frequency amplifier and configured to receive a local oscillator (LO) signal, where the common mode cancellation input port is configured to receive a common mode leakage signal associated with the LO signal. The circuitry can further include a transformer coupled to the output or input port of the radio-frequency amplifier and one or more passive components coupled between the transformer and the common mode cancellation input port of the power detection circuit. The one or more passive components can include an adjustable capacitor or an adjustable resistor that is trimmed to fully cancel out or only partially cancel out a common mode leakage signal received at the first and second input transistors.

An aspect of the disclosure provides circuitry that includes a passive circuit, a transformer having a first coil coupled to the passive circuit and having a second coil, and a power detector having a differential input port coupled to the first coil of the transformer and having a common mode cancellation input port, separate from the differential input port, coupled to a center tap of the first coil of the transformer. The power detector can include a first input transistor having a gate terminal coupled to the differential input port of the power detector, a second input transistor having a gate terminal coupled to the differential input port of the power detector, and a third input transistor having a gate terminal coupled to the common mode cancellation input port of the power detector.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry having radio-frequency amplifiers in accordance with some embodiments.

FIG. 3 is a diagram showing illustrative power detectors coupled to radio-frequency amplifier outputs in accordance with some embodiments.

FIG. 4 is a diagram of an illustrative power detector tapping a common mode at an input port of the power detector in accordance with some embodiments.

FIG. 5 is a diagram of an illustrative power detector tapping a common mode across terminals of a secondary transformer coil in accordance with some embodiments.

FIG. 6 is a diagram of an illustrative power detector tapping a common mode at a center tap terminal of a secondary transformer coil in accordance with some embodiments.

FIG. 7 is a circuit diagram of an illustrative power detector having a replica input transistor configured to receive a common mode leakage signal in accordance with some embodiments.

FIG. 8 is a diagram of an illustrative power detector tapping a common mode at a center tap terminal of a primary transformer coil in accordance with some embodiments.

FIG. 9 is a diagram of an illustrative power detector coupled to an input port of a radio-frequency amplifier in accordance with some embodiments.

### DETAILED DESCRIPTION

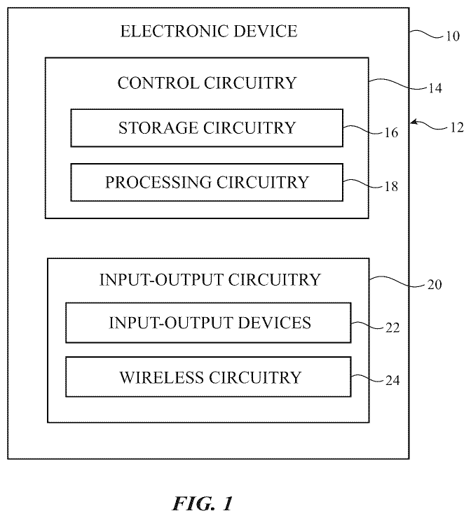

An electronic device such as device 10 of FIG. 1 may be provided with wireless circuitry. Wireless circuitry can include radio-frequency amplifiers such as power amplifiers and low noise amplifiers. Power amplifiers can be used to amplify radio-frequency signals in a transmit path, whereas low noise amplifiers can be used to amplify radio-frequency signals in a receive path. Power detection circuits, sometimes referred to as power detectors, can be coupled at the outputs of these radio-frequency amplifiers. A power detector coupled at the output of a radio-frequency power amplifier can be configured to run an adaptive power control algorithm for adjusting a power level of the power amplifier, whereas a power detector coupled at the output of a radio-frequency low noise amplifier can be used to run an automatic gain control algorithm for adjusting a power level of the low noise amplifier.

Other circuits such as a mixer can be coupled to the output of a radio-frequency (RF) amplifier. A mixer can receive high frequency local oscillator (LO) signals, which can generate common mode signals and/or other spurs that can leak into the input of the power detector. If care is not taken, this common mode leakage can degrade the dynamic range of the power detector. To help cancel out such common mode leakage, the power detector can tap into common mode signals along various portions of the signal path. In one embodiment, the power detector can tap the common mode signal at the differential input port of the power detector. In another embodiment, the power detector can tap the common mode signal across opposing terminals of a transformer secondary coil at the input of the mixer. In yet another embodiment, the power detector can tap the common mode signal at a center tap terminal of a transformer secondary coil at the input of the mixer. The common mode signal can be coupled to a replica input transistor within the power detector via an optional adjustable coupling component. Configuring and operating a power detector in this way can be technically advantageous and beneficial to improve the dynamic range of the power detector while improving the detector accuracy (e.g., to improve the signal-to-noise ratio) over process, voltage, and temperature variations.

Electronic device 10 of FIG. 1 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more microprocessors, microcontrollers, digital signal processors, host processors, baseband processor integrated circuits, application specific integrated circuits, central processing units (CPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols-sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 5G protocols, etc.), antenna diversity protocols, satellite navigation system protocols (e.g., global positioning system (GPS) protocols, global navigation satellite system (GLONASS) protocols, etc.), antenna-based spatial ranging protocols (e.g., radio detection and ranging (RADAR) protocols or other desired range detection protocols for signals conveyed at millimeter and centimeter wave frequencies), or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support wireless communications. Wireless circuitry 24 (sometimes referred to herein as wireless communications circuitry 24) may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s).

Wireless circuitry 24 may transmit and/or receive radio-frequency signals within a corresponding frequency band at radio frequencies (sometimes referred to herein as a communications band or simply as a “band”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network (WPAN) frequency bands such as the 2.4 GHz Bluetooth® band or other WPAN communications bands, cellular telephone frequency bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), cellular sidebands, 6G bands between 100-1000 GHz (e.g., sub-THz, THz, or tremendously high frequency bands, etc.), other centimeter or millimeter wave frequency bands between 10-300 GHz, near-field communications frequency bands (e.g., at 13.56 MHz), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, and/or any other desired frequency bands of interest.

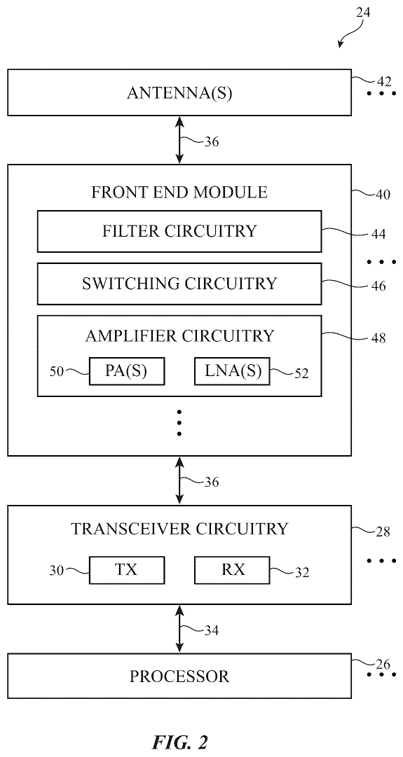

FIG. 2 is a diagram showing illustrative components within wireless circuitry 24. As shown in FIG. 2, wireless circuitry 24 may include a processor such as processor 26, radio-frequency (RF) transceiver circuitry such as radio-frequency transceiver 28, radio-frequency front end circuitry such as radio-frequency front end module (FEM) 40, and antenna(s) 42. Processor 26 may be a baseband processor, application processor, general purpose processor, microprocessor, microcontroller, digital signal processor, host processor, application specific signal processing hardware, or other type of processor. Processor 26 may be coupled to transceiver 28 over path 34. Transceiver 28 may be coupled to antenna 42 via radio-frequency transmission line path 36. Radio-frequency front end module 40 may be disposed on radio-frequency transmission line path 36 between transceiver 28 and antenna 42.

In the example of FIG. 2, wireless circuitry 24 is illustrated as including only a single processor 26, a single transceiver 28, a single front end module 40, and a single antenna 42 for the sake of clarity. In general, wireless circuitry 24 may include any desired number of processors 26, any desired number of transceivers 28, any desired number of front end modules 40, and any desired number of antennas 42. Each processor 26 may be coupled to one or more transceiver 28 over respective paths 34. Each transceiver 28 may include a transmitter circuit 30 configured to output uplink signals to antenna 42, may include a receiver circuit 32 configured to receive downlink signals from antenna 42, and may be coupled to one or more antennas 42 over respective radio-frequency transmission line paths 36. Each radio-frequency transmission line path 36 may have a respective front end module 40 disposed thereon. If desired, two or more front end modules 40 may be disposed on the same radio-frequency transmission line path 36. If desired, one or more of the radio-frequency transmission line paths 36 in wireless circuitry 24 may be implemented without any front end module disposed thereon.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is merely illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards.

In performing wireless transmission, processor 26 may provide transmit signals (e.g., digital or baseband signals) to transceiver 28 over path 34. Transceiver 28 may further include circuitry for converting the transmit (baseband) signals received from processor 26. For example, transceiver circuitry 28 may include mixer circuitry for up-converting (or modulating) the transmit (baseband) signals to radio frequencies prior to transmission over antenna 42. The example of FIG. 2 in which processor 26 communicates with transceiver 28 is merely illustrative. In general, transceiver 28 may communicate with a baseband processor, an application processor, general purpose processor, a microcontroller, a microprocessor, or one or more processors within circuitry 18. Transceiver circuitry 28 may also include digital-to-analog converter (DAC) and/or analog-to-digital converter (ADC) circuitry for converting signals between digital and analog domains. Transceiver 28 may use transmitter (TX) 30 to transmit the radio-frequency signals over antenna 42 via radio-frequency transmission line path 36 and front end module 40. Antenna 42 may transmit the radio-frequency signals to external wireless equipment by radiating the radio-frequency signals into free space.

In performing wireless reception, antenna 42 may receive radio-frequency signals from the external wireless equipment. The received radio-frequency signals may be conveyed to transceiver 28 via radio-frequency transmission line path 36 and front end module 40. Transceiver 28 may include circuitry such as receiver (RX) 32 for receiving signals from front end module 40 and for converting the received radio-frequency signals into corresponding baseband signals. For example, transceiver 28 may include mixer circuitry for down-converting (or demodulating) the received radio-frequency signals to baseband frequencies prior to conveying the received signals to processor 26 over path 34.

Front end module (FEM) 40 may include radio-frequency front end circuitry that operates on the radio-frequency signals conveyed (transmitted and/or received) over radio-frequency transmission line path 36. FEM 40 may, for example, include front end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifier circuits 50 and/or one or more low-noise amplifier circuits 52), signal attenuators, impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front end module components may be mounted to a common (shared) substrate such as a rigid printed circuit board substrate or flexible printed circuit substrate. If desired, the various front end module components may also be integrated into a single integrated circuit chip. If desired, amplifier circuitry 48 and/or other components in front end 40 such as filter circuitry 44 may also be implemented as part of transceiver circuitry 28.

Filter circuitry 44, switching circuitry 46, amplifier circuitry 48, and other circuitry may be disposed along radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Transceiver 28 may be separate from front end module 40. For example, transceiver 28 may be formed on another substrate such as the main logic board of device 10, a rigid printed circuit board, or flexible printed circuit that is not a part of front end module 40. While control circuitry 14 is shown separately from wireless circuitry 24 in the example of FIG. 1 for the sake of clarity, wireless circuitry 24 may include processing circuitry that forms a part of processing circuitry 18 and/or storage circuitry that forms a part of storage circuitry 16 of control circuitry 14 (e.g., portions of control circuitry 14 may be implemented on wireless circuitry 24). As an example, processor 26 and/or portions of transceiver 28 (e.g., a host processor on transceiver 28) may form a part of control circuitry 14. Control circuitry 14 (e.g., portions of control circuitry 14 formed on processor 26, portions of control circuitry 14 formed on transceiver 28, and/or portions of control circuitry 14 that are separate from wireless circuitry 24) may provide control signals (e.g., over one or more control paths in device 10) that control the operation of front end module 40.

Transceiver circuitry 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHZ, 3G bands, 4G LTE bands, 5G New Radio Frequency Range 1 (FR1) bands below 10 GHz, 5G New Radio Frequency Range 2 (FR2) bands between 20 and 60 GHz, etc.), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, radio transceiver circuitry that handles unlicensed radio bands reserved for industrial, scientific, and medical (ISM) purposes, and/or any other desired radio-frequency transceiver circuitry for covering any other desired communications bands of interest.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

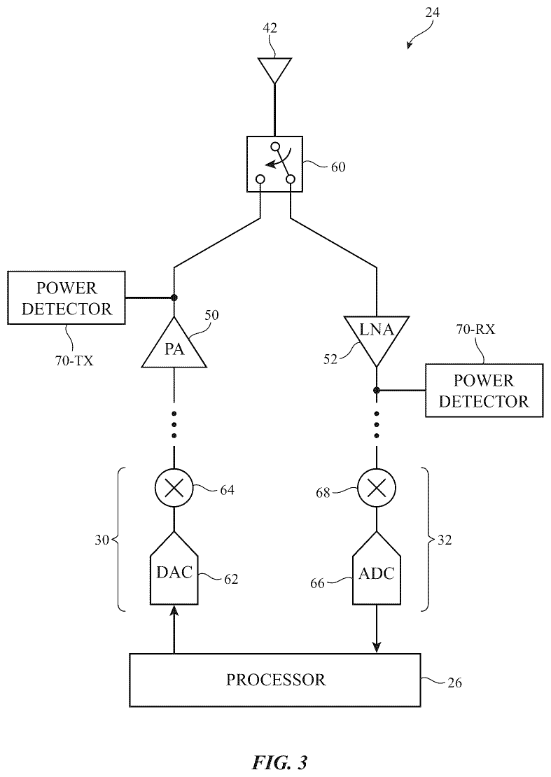

Radio-frequency amplifiers may be coupled to power detectors for power level monitoring purposes. FIG. 3 is a diagram showing illustrative power detectors coupled to radio-frequency amplifier outputs. As shown in FIG. 3, wireless circuitry 24 can have one or more antenna 42 that is coupled to a transmit path and a receive path via a radio-frequency duplexing circuit such as duplexer 60. Duplexer 60 may have a first port coupled to a shared antenna 42, a second port coupled to the transmit path (e.g., a second port configured to receive amplified radio-frequency signals to be radiated by antenna 42), and a third port coupled to the receive path (e.g., a third port to which radio-frequency signals received by antenna 42 are conveyed).

The receive path can include low noise amplifier (LNA) circuitry 52, a downconverting mixing circuit such as mixer 68, and a data converter such as analog-to-digital converter (ADC) 66. The LNA circuitry 52 can include one or more amplifiers coupled in series and/or in parallel. Mixer 68 may use a local oscillator signal to downconvert (or demodulate) the radio-frequency signals to baseband (or intermediate) frequencies. Analog-to-digital converter (ADC) circuit 66 can then convert the demodulated signals from the analog domain to the digital domain to generate corresponding digital baseband signals. Mixer 68 and ADC circuit 66 are sometimes be considered part of receiver circuitry 32. The digital baseband signals can then be received by one or more processors 26. Processor 26 may represent one or more processors such as a baseband processor, an application processor, a digital signal processor, a microcontroller, a microprocessor, a central processing unit (CPU), a programmable device, a combination of these circuits, and/or one or more processors within circuitry 18 (see FIG. 1).

The circuitry described above for processing signals received by antenna 42 is sometimes referred to collectively as wireless receiving circuitry. If desired, one or more additional front end module components such as radio-frequency filter circuitry 44 of FIG. 2 (e.g., low pass filters, high pass filters, notch filters, band pass filters, attenuators, multiplexing circuitry, duplexer circuitry, diplexer circuitry, triplexer circuitry, etc.), switching circuitry 46 (e.g., one or more radio-frequency switches), impedance matching circuitry, antenna tuning circuitry (e.g., networks of capacitors, resistors, inductors, and/or switches that adjust the frequency response of antenna 42), radio-frequency coupler circuitry, charge pump circuitry, power management circuitry, and/or any other desired front-end module circuitry can optionally be coupled at the input and/or output of LNA circuitry 52 along the radio-frequency reception line path.

On the other hand, the transmit path can include power amplifier (PA) circuitry 50, a upconverting mixing circuit such as mixer 64, and a data converter such as digital-to-analog converter (DAC) 62. Processor 26 can generate digital baseband signals, sometimes referred to as digital signals for transmission. DAC circuit 62 can convert the digital baseband signals from the digital domain to the analog domain to generate corresponding analog baseband signals. Mixer 64 may use a local oscillator signal to upconvert (or modulate) the radio-frequency signals to radio (or intermediate) frequencies. DAC circuit 62 and mixer 64 are sometimes be considered part of transmitter circuitry 30. The upconverted radio-frequency signals can then be fed to amplifier circuitry 50. The PA circuitry 52 can include one or more amplifiers coupled in series and/or in parallel that are configured to amplify signals for transmission by antenna 42.

The circuitry described above for preparing signals for transmission by antenna 42 is sometimes referred to collectively as wireless transmitting circuitry. If desired, one or more additional front end module components such as radio-frequency filter circuitry 44 of FIG. 2 (e.g., low pass filters, high pass filters, notch filters, band pass filters, attenuators, multiplexing circuitry, duplexer circuitry, diplexer circuitry, triplexer circuitry, etc.), switching circuitry 46 (e.g., one or more radio-frequency switches), impedance matching circuitry, antenna tuning circuitry (e.g., networks of capacitors, resistors, inductors, and/or switches that adjust the frequency response of antenna 42), radio-frequency coupler circuitry, charge pump circuitry, power management circuitry, and/or any other desired front-end module circuitry can optionally be coupled at the input and/or output of amplifier circuitry 50 along the radio-frequency transmission line path.

Power (transmitting) amplifiers 50 and low noise (receiving) amplifiers 52 can be referred to collectively as radio-frequency amplifiers. Power detection circuits can be coupled to the outputs of the radio-frequency amplifiers to enable power monitoring operations. Still referring to FIG. 3, a first power detection circuit such as power detector 70-TX may be coupled to the output of transmitting amplifier circuitry 50, whereas a second power detection circuit such as power detector 70-RX may be coupled to the output of receiving amplifier circuitry 52. Power detector 70-TX can be used to detect or measure an output power level of radio-frequency signals generated at the output of amplifier circuitry 50. The detected output power level can then be used by an automatic power control (APC) algorithm to dynamically adjust the gain of power amplifier circuitry 50 to ensure that the transmit path is outputting signals at desired power levels. The APC algorithm, which can run on processor 26 or other control circuitry in device 10, can compare the measured output power level to a reference power level. If the output power level is too high, the APC algorithm can reduce the gain of amplifier 50. If the output power level is too low, the APC algorithm can increase the gain of amplifier 50.

Power detector 70-RX can be used to detect or measure an output power level of radio-frequency signals generated at the output of receiving amplifier circuitry 52. The detected output power level can then be used by an automatic gain control (AGC) algorithm to dynamically adjust the gain of LNA circuitry 52 to ensure that the receive path is outputting signals at desired power levels regardless of the strength of signals arriving at the input of circuitry 52. The AGC algorithm, which can run on processor 26 or other control circuitry in device 10, can be used to ensure that signals are output from circuitry 52 at a constant output power level. If the input signal is weak, the AGC algorithm can increase the gain of amplifier 52 to maintain constant output level. If the input signal is strong, then the AGC algorithm can reduce the gain of amplifier 52 to prevent the output level from becoming too high.

The example of FIG. 3 in which power detectors 70-TX and 70-RX are coupled at the radio-frequency amplifier outputs is illustrative. If desired, one or more power detectors can be coupled at the output of DAC 62, at the output of mixer 64, and/or at any other point(s) along the transmit signal path, at the output of mixer 68, at the output of ADC 66, and/or at any other point(s) along the receive signal path.

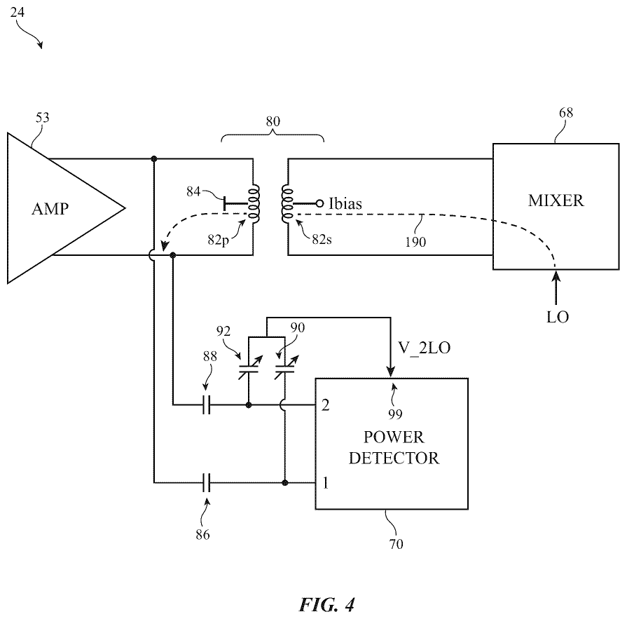

FIG. 4 is a diagram of wireless circuitry 24 having a radio-frequency amplifier 53 having an output port coupled to mixer 68 via a transformer 80. Radio-frequency amplifier 53 can represent a variable gain amplifier (VGA), low noise amplifier 52 of FIG. 3, or other amplifying circuit along the receive signal path. Transformer 80 may be coupled between the output port of radio-frequency amplifier 53 and an input port of mixer 68. Radio-frequency amplifier 53 may be a differential amplifier with a differential output port. Similarly, mixer 68 may be a differential mixing circuit with a differential input port. Transformer 80 may include a primary coil (winding) 82p and a secondary coil (winding) 82s. Primary coil 82p may have opposing (distal) terminals coupled across the differential output port of RF amplifier 53 and a center tap terminal coupled to a voltage line 84. Voltage line 84 can be supplied with a fixed bias voltage, a power supply voltage, or other fixed or adjustable voltage. Secondary coil 82s may have opposing (distal) terminals coupled across the differential input port of mixer 68 and a center tap terminal configured to receive a bias current Ibias.

The differential output port of RF amplifier 53 may be coupled to a power detector such as power detector 70. The power detector 70 of FIG. 4 that is coupled to a receiving amplifier 53 may correspond to power detector 70-RX of FIG. 3 (as an example). In particular, power detector 70 may have a differential input port that is coupled to the differential output port of RF amplifier 53 via coupling capacitors 86 and 88. Capacitor 86 may have a first terminal coupled to a first terminal of primary coil 82p and a second terminal coupled to a first input of power detector 70. Capacitor 88 may have a first terminal coupled to a second terminal of primary coil 82p and a second terminal coupled to a second input of power detector 70. The first and second inputs of power detector 70 may serve collectively as the differential input port of power detector 70.

Power detector 70 can including signal squaring components (cells) with signal squaring functionality. Power detectors based on squarers can exhibit similar gain for differential mode and common mode signals at their inputs (i.e., the squaring cells can detect both differential mode and common mode signals). Mixer 68 can further receive high frequency local oscillator (LO) signals, sometimes referred to as oscillating signals. If care is not taken, the LO signal received at mixer 68 can leak into the input port of power detector 70, as shown by leakage path 190. For example, a second harmonic LO (2LO) component can leak into the power detector input as a common mode signal. Common mode signals on the signal path such as LO leakage, 2LO leakage, and/or other spurs at the power detector input can lead to generation of a spurious voltage at the output of power detector 70, which can degrade the dynamic range of power detector 70. In some instances, the 2LO leakage can dominate the detected signal strength response and can dramatically reduce the dynamic range of power detector 70. Such common mode signal(s) that degrade the dynamic range of power detector 70, sometimes referred to and defined herein as “common mode leakage,” may be generated due to non-ideal conductive and/or magnetic coupling and can cause incorrect operation of the power/gain control algorithm associated with amplifier 53, which can degrade the signal-to-noise radio (SNR) of the overall system.

In accordance with some embodiments, power detector 70 can tap a common mode signal from various points in the signal path between amplifier 53 and mixer 68. In the example of FIG. 4, the common mode signal (or leakage) can be tapped from the differential input port of power detector 70. As shown in FIG. 4, a first common mode tapping capacitor 90 and a second common mode tapping capacitor 92 can be coupled between the differential input port of power detector 70 and a common mode cancellation input port 99 of power detector 70. First common mode tapping capacitor 90 may have a first terminal coupled to the first input port of power detector 70 and a second terminal coupled to common mode cancellation input port 99. Second common mode tapping capacitor 92 may have a first terminal coupled to the second input port of power detector 70 and a second terminal also coupled to common mode cancellation input port 99. Configured in this way, common mode leakage including a second harmonic LO voltage V_2LO and other undesirable common mode spurious signal(s) can be coupled from mixer 68 to input port 99. The common mode signal(s) being fed into input port 99 of power detector 70 can be used cancel out any undesired common mode leakage at the output port of power detector 70. Configured and operated in this way, the dynamic range of power detector 70 can be optimized. Capacitors 90 and 92 may optionally be implemented as adjustable or trimmable capacitors that are trimmed to fully cancel out the common mode leakage or to limit the common mode leakage to a target voltage level based on the desired dynamic range or accuracy of power detector 70.

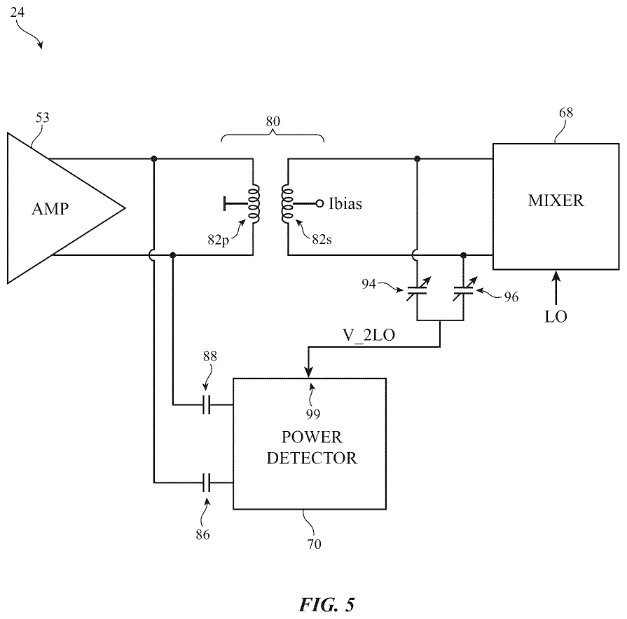

The embodiment of FIG. 4 in which additional common mode tapping capacitors 90 and 92 are connected to the differential input port of power detector 70 is exemplary and can introduce extra loading on the main signal. FIG. 5 shows another embodiment in which the common mode is tapped across the transformer secondary coil 82s. As shown in FIG. 5, a first common mode tapping capacitor 94 and a second common mode tapping capacitor 96 can be coupled between secondary coil 82s and common mode cancellation input port 99 of power detector 70. First common mode tapping capacitor 94 may have a first terminal coupled to a first terminal (upper distal terminal in FIG. 5) of secondary coil 82s and a second terminal coupled to common mode cancellation input port 99. Second common mode tapping capacitor 96 may have a first terminal coupled to a second terminal (lower distal terminal in FIG. 5) of secondary coil 82s and a second terminal coupled to common mode cancellation input port 99. Configured in this way, common mode leakage including a second harmonic LO voltage V_2LO and other undesirable common mode spurious signal(s) can be coupled from mixer 68 to input port 99. The common mode signal(s) being fed into input port 99 of power detector 70 can be used cancel out any undesired common mode leakage at the output port of power detector 70. Configured and operated in this way, the dynamic range of power detector 70 can be optimized. Capacitors 94 and 96 may optionally be implemented as adjustable or trimmable capacitors that are trimmed to fully cancel out the common mode leakage or to limit the common mode leakage to a target voltage level based on the desired dynamic range or accuracy of power detector 70.

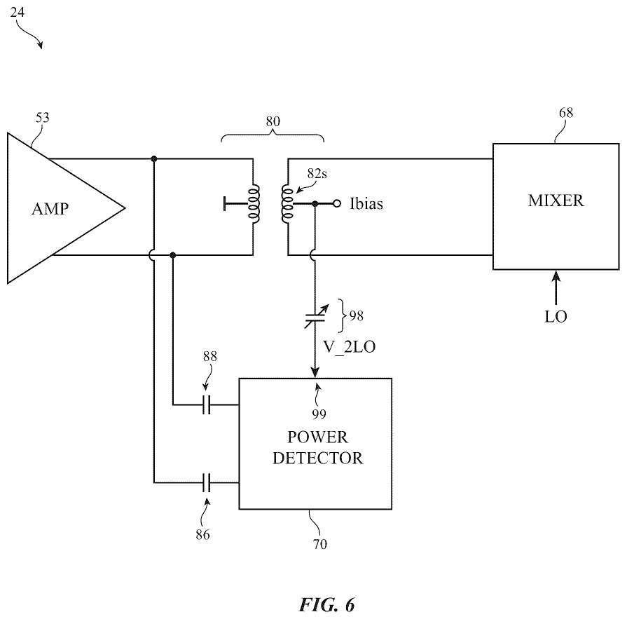

The embodiment of FIG. 5 in which additional common mode tapping capacitors 94 and 96 are connected across the opposing terminals of secondary coil 82s in transformer 80 is exemplary and can sense larger common mode signals relative to the embodiment of FIG. 4 but may still introduce extra loading on the main signal. FIG. 6 shows yet another embodiment in which the common mode signal is tapped at the center tap terminal the transformer secondary coil 82s. As shown in FIG. 6, a common mode tapping capacitor 98 can be coupled between secondary coil 82s and common mode cancellation input port 99 of power detector 70. Common mode tapping capacitor 98 may have a first terminal coupled to the center tap terminal of secondary coil 82s and a second terminal coupled to common mode cancellation input port 99. Configured in this way, common mode leakage including a second harmonic LO voltage V_2LO and other undesirable common mode spurious signal(s) can be coupled from mixer 68 to input port 99. The common mode signal(s) being fed into input port 99 of power detector 70 can be used cancel out any undesired common mode leakage at the output port of power detector 70. Configured and operated in this way, the dynamic range of power detector 70 can be optimized.

Compared to the examples of FIGS. 4 and 5, the embodiment of FIG. 6 has no impact on the radio-frequency performance since the center tap of secondary coil 82s behaves like an AC ground node for differential mode operation. This can result in better common mode leakage cancellation within power detector 70. Capacitor 98 can have an adjustable or trimmable capacitance. In some instances, capacitor 98 can be trimmed to completely (entirely) cancel out the common mode leakage. In other instances, capacitor 98 can be trimmed so that the common mode leakage is tuned to a target voltage level at the power detector output (e.g., capacitor 98 is trimmed to only partially cancel out the common mode leakage). The amount or degree of trimming can be determined based on the desired dynamic range or accuracy of power detector 70.

The example of FIG. 6 in which an adjustable capacitance 98 is coupled between the center tap of secondary coil 82s and common mode cancellation input port 99 is illustrative. In other embodiments, an adjustable or trimmable resistor can be coupled between the center tap of secondary coil 82s and common mode cancellation input port 99. Such resistor can similarly be trimmed to fully cancel out the common mode leakage or to limit the common mode leakage to a target voltage level based on the desired dynamic range or accuracy of power detector 70.

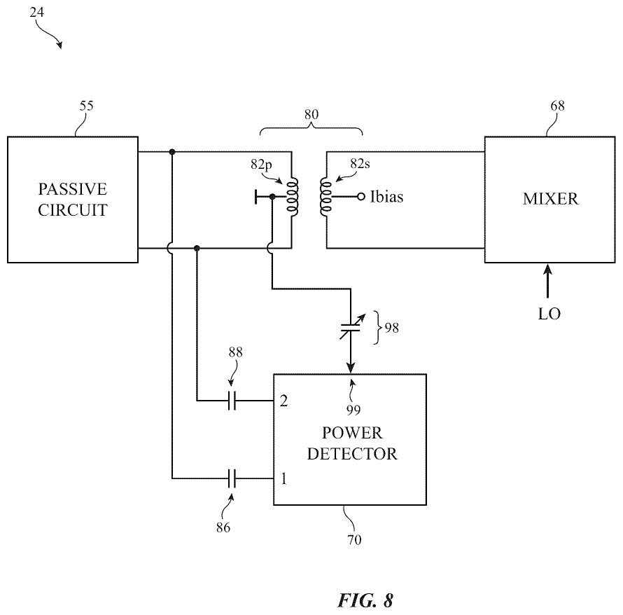

The embodiment of FIG. 6 in which trimmable capacitor 98 is coupled to the center tap of secondary coil 82s is illustrative. FIG. 8 shows yet another embodiment in which the common mode signal is tapped at the center tap terminal the transformer primary coil 82p. This common mode tapping point can be employed when primary coil 82p of transformer 80 is coupled to a passive circuit such as passive circuit 55. Passive circuit 55 can be an attenuator, a phase shifter, or other passive circuit along the receive or transmit path. As shown in FIG. 8, common mode tapping capacitor 98 can be coupled between primary coil 82p and common mode cancellation input port 99 of power detector 70. Common mode tapping capacitor 98 may have a first terminal coupled to the center tap terminal of primary coil 82p and a second terminal coupled to common mode cancellation input port 99. Configured in this way, common mode leakage including a second harmonic LO voltage V_2LO and other undesirable common mode spurious signal(s) can be coupled from mixer 68 to input port 99. The common mode signal(s) being fed into input port 99 of power detector 70 can be used cancel out any undesired common mode leakage at the output port of power detector 70. Configured and operated in this way, the dynamic range of power detector 70 can be optimized.

Similar to the embodiment of FIG. 6, the embodiment of FIG. 8 has no impact on the radio-frequency performance since the center tap of primary coil 82p behaves like an AC ground node for differential mode operation. This can result in better common mode leakage cancellation within power detector 70. Capacitor 98 can have an adjustable or trimmable capacitance. In some instances, capacitor 98 can be trimmed to completely (entirely) cancel out the common mode leakage. In other instances, capacitor 98 can be trimmed so that the common mode leakage is tuned to a target voltage level at the power detector output (e.g., capacitor 98 is trimmed to only partially cancel out the common mode leakage). The amount or degree of trimming can be determined based on the desired dynamic range or accuracy of power detector 70. The example of FIG. 8 in which an adjustable capacitance 98 is coupled between the center tap of primary coil 82p and common mode cancellation input port 99 is illustrative. In other embodiments, an adjustable or trimmable resistor can be coupled between the center tap of primary coil 82p and common mode cancellation input port 99. Such resistor can similarly be trimmed to fully cancel out the common mode leakage or to limit the common mode leakage to a target voltage level based on the desired dynamic range or accuracy of power detector 70.

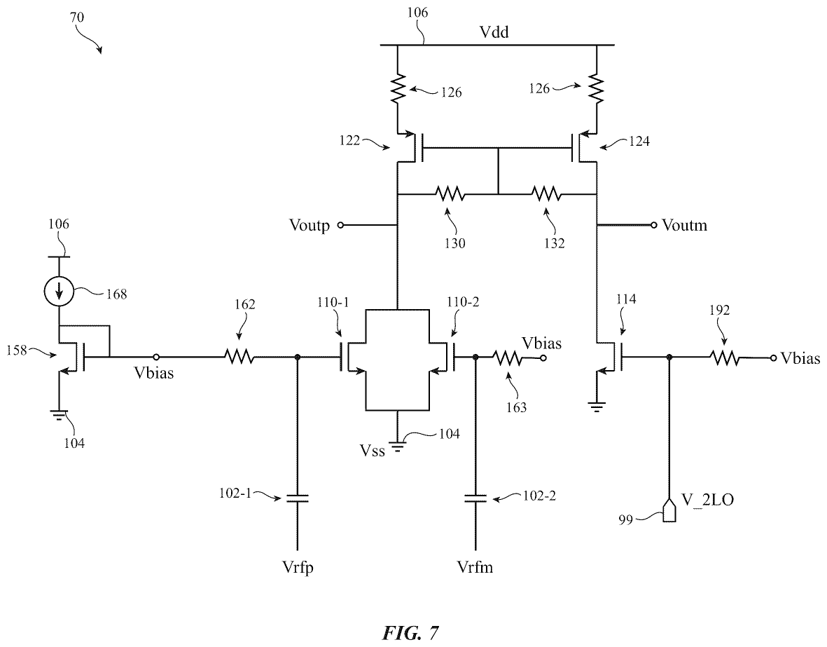

FIG. 7 is a circuit diagram of power detector 70 of the type described in connection with FIGS. 3-6 and 8. As shown in FIG. 7, power detection circuit 70 may include input transistors such as first input transistor 110-1 and second input transistor 110-2, a replica input transistor such as replica input transistor 114, and load transistors such as a first load transistor 122 and a second load transistor 124. First input transistor 110-1 may have the same size as second input transistor 110-2. Replica input transistor 114 may refer to and be defined herein has a transistor having similar connections and bias conditions as the input transistors 110-1 and 110-2 and having a size that is equal to the combined sizing of input transistors 110-1 and 110-2. Since there are two input transistors 110-1 and 110-2 with identical sizing, replica input transistor 114 may have a sizing that is equal to twice the size of input transistor 110-1. In embodiments where power detector 70 only has a single input transistor 110, then replica input transistor 114 may have identical sizing as that single input transistor 110.

Transistors 110-1, 110-2, and 114 can be n-type metal-oxide-semiconductor (NMOS) transistors, whereas load transistors 122 and 124 can be p-type metal-oxide-semiconductor (PMOS) transistors. First input transistor 110-1 may have a gate terminal coupled to a first input terminal configured to receive first (positive) radio-frequency signal Vrfp via an alternating current (AC) coupling capacitor 102-1, a source terminal coupled to a ground line 104 (e.g., a ground power supply line on which ground voltage Vss is provided), and a drain terminal coupled to a first power detector output terminal on which first (positive) power detector output voltage Voutp is provided. Second input transistor 110-2 may have a gate terminal coupled to a second input terminal configured to receive second (minus/negative) radio-frequency signal Vrfm via a second AC coupling capacitor 102-2, a source terminal coupled to ground line 104, and a drain terminal also coupled to the first power detector output terminal. The first and second input transistors 110-1 and 110-2 may be coupled together in parallel. The first and second input terminals that receive differential voltages Vrfp and Vrfm may collectively serve as the differential input port of power detector 70 (which can be connected to the differential output port of amplifier 53 as shown in FIGS. 4-6), whereas the first and second power detector output terminals on which differential voltages Voutp and Voutm are generated may collectively serve as the differential output port of power detector 70.

The terms “source” and “drain” are sometimes used interchangeably when referring to current-conducting terminals of a metal-oxide-semiconductor transistor. The source and drain terminals are therefore sometimes referred to as “source-drain” terminals (e.g., a transistor has a gate terminal, a first source-drain terminal, and a second source-drain terminal).

Replica input transistor 114 may have a source terminal coupled to the ground line, a gate terminal configured to receive a bias voltage Vbias via a series resistor 192, and a drain terminal coupled to a second power detector output terminal on which second (minus/negative) power detector output voltage Voutm is provided. Resistor 192 is optional. Configured in this way, the input transistors 110-1 and 110-2 and replica input transistor 114 may be operated to perform an AC voltage to DC current conversion and is sometimes referred to as an AC-to-DC converter or a squaring subcircuit or cell (e.g., a circuit configured to perform a squaring function x² for an input signal x, where x is equal to a differential signal Vrfp minus Vrfm).

The embodiment of FIG. 7 in which the drain terminals of input transistors 110-1 and 110-2 are directly connected to the first power detector output terminal and where the drain terminal of replica input transistor 114 is directly connected to the second power detector output terminal is illustrative. If desired, a first cascode transistor can optionally be coupled in series between input transistor 110-1 and the first power detector output terminal, and a second cascode transistor can optionally be coupled in series between replica input transistor 114 and the second power detector output terminal.

Load transistor 122 may have a drain terminal coupled to the first power detector output terminal, a gate terminal that is coupled to its own drain terminal via resistor 130, and a source terminal coupled to power supply line 106 (e.g., a positive power supply line on which supply voltage Vdd is provided) via a first source resistor 126. Load transistor 122 is therefore coupled in series with the first and second input transistors 110-1 and 110-2. Similarly, load transistor 124 may have a drain terminal coupled to the second power detector output terminal, a gate terminal that is coupled to its own drain terminal via resistor 132, and a source terminal coupled to power supply line 106 via a second source resistor 126. Load transistor 124 is therefore coupled in series with replica input transistor 114. Source resistors 126 are optional.

The input transistors 110-1 and 110-2 can also be configured to receive the same bias voltage Vbias as replica input transistor 114. The gate terminal of second input transistor 110-2 may be configured to receive bias voltage Vbias via series resistor 163. Resistor 163 is optional. Similarly, the gate terminal of first input transistor 110-1 may be configured to receive bias voltage Vbias via series resistor 162. Resistor 162 is also optional. Bias voltage Vbias can be generated using an associated bias voltage generation circuit that includes a current source 168 and bias transistor 158. Bias transistor 158 may be an NMOS transistor (as an example).

Bias transistor 158 may have a drain terminal coupled in series with current source 168, a source terminal coupled to ground power supply line 104, and a gate terminal shorted to its own drain terminal. Current source 168 can optionally be implemented using a current mirror circuit (as an example). Bias transistor 158 having gate and drain terminal that are shorted together can be referred to and defined herein as a “diode-connected” transistor. Arranged in this way, diode-connected bias transistor 158 may provide bias voltage Vbias to the gate terminals of input transistor 110-1 and 110-2 and replica input transistor 114. In general, other types of bias voltage generation circuit can be employed. The example of FIG. 7 in which transistors 110-1, 110-2, and 114 all receive the same bias voltage Vbias is illustrative. As another example, replica input transistor 114 can optionally be configured to receive a different bias voltage than the input transistors 110-1 and 110-2. As yet another example, transistors 110-1, 110-2, and 114 can each be configured to receive a different respective bias voltage.

As shown in FIG. 7, the gate terminal of replica input transistor 114 may serve as the common mode cancellation input port 99 of power detector 70. Configured in this way, the second harmonic LO voltage V_2LO and other undesirable common mode leakage/spurious signal(s) can be coupled from mixer 68 to the gate terminal of replica input transistor 114. In the embodiment of FIG. 4, the gate terminal of replica input transistor 114 would be shorted to the second terminals of common mode tapping capacitors 90 and 92. In the embodiment of FIG. 5, the gate terminal of replica input transistor 114 would be shorted to the second (lower) terminals of common mode tapping capacitors 94 and 96. In the embodiment of FIG. 6, the gate terminal of replica input transistor 114 would be shorted to the second (lower) terminal of capacitor 98.

As described above in connection with at least FIG. 4, common mode leakage signals such as 2LO can leak into the differential input port of power detector 70 into the gate terminals of input transistors 110-1 and 110-2 (see, e.g., leakage path 190). Here, simultaneously feeding the tapped common mode leakage signals into the gate terminal of replica input transistor 114 results in the same common mode leakage signals to be generated at the first and second power detector output terminals. Since power detector 70 is operated in a differential mode, the common mode leakage signals can be canceled out across the differential output port of power detector 70. This common mode cancellation scheme is technically advantageous and beneficial to improve the dynamic range and accuracy of power detector 70 across a broad range of process, voltage, and temperature (PVT) variations, which can also improve system calibration accuracy and signal-to-noise ratio.

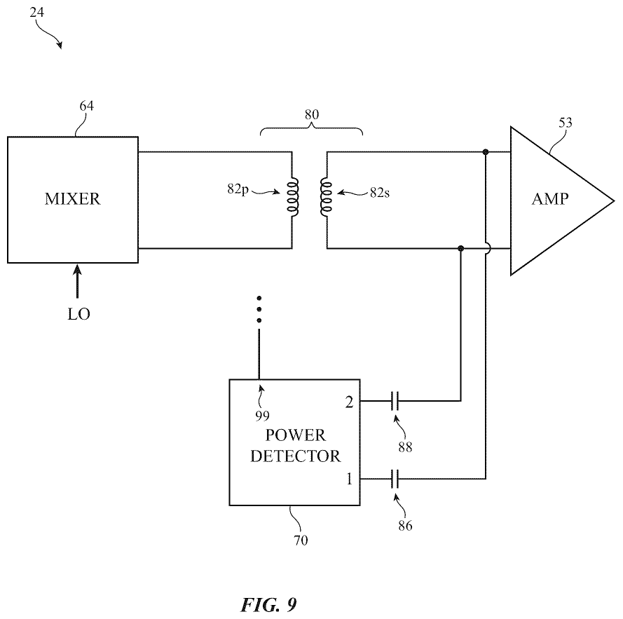

The embodiments of FIGS. 4-6 in which power detector 70 is coupled to the output port of a receiving amplifier are exemplary. If desired, the common mode cancellation techniques described herein can also be extended to a power detector with an input port coupled along a transmit path (see, e.g., FIG. 9). As shown in FIG. 9, the transmit components in wireless circuitry 24 may include a mixer 64, a radio-frequency amplifier 53, and transformer 80 coupled between mixer 64 and amplifier 53. Radio-frequency amplifier 53 can represent a variable gain amplifier (VGA), power amplifier 50 of FIG. 3, or other amplifying circuit along the transmit signal path. Transformer 80 may be coupled between an output port of mixer 64 and an input port of amplifier 53. Radio-frequency amplifier 53 may be a differential amplifier with a differential input port. Similarly, mixer 64 may be a differential mixing circuit with a differential output port. Transformer 80 may include a primary coil (winding) 82p and a secondary coil (winding) 82s. Primary coil 82p may have opposing (distal) terminals coupled across the differential output port of mixer 64. Secondary coil 82s may have opposing (distal) terminals coupled across the differential input port of RF amplifier 53.

Power detector 70 may have a differential input port coupled to the differential input port of amplifier 53 via respective coupling capacitors 86 and 88. In accordance with some embodiments, power detector 70 may have a separate common mode cancellation input port coupled to the differential input port of detector 70, to primary coil 82p (e.g., the common mode cancellation input port can be coupled across opposing terminals of primary coil 82p or to a center tap terminal of primary coil 82p), or optionally to the secondary coil 82s via one or more adjustable capacitors or resistors. Configured in this way, common mode leakage including a second harmonic LO voltage V_2LO and other undesirable common mode spurious signal(s) can be coupled from mixer 64 to input port 99. The common mode signal(s) being fed into input port 99 of power detector 70 can be used cancel out any undesired common mode leakage at the output port of power detector 70. Configured and operated in this way, the dynamic range of power detector 70 can be optimized.

The methods and operations described above in connection with FIGS. 1-9 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

The foregoing is merely illustrative and various modifications can be made to the described embodiments. The foregoing embodiments may be implemented individually or in any combination.

What is claimed is:

1. Wireless circuitry comprising:
a radio-frequency amplifier;
a mixer coupled to the radio-frequency amplifier and configured to receive an oscillating signal; and
a power detection circuit having an input port coupled to the radio-frequency amplifier and having a common mode cancellation input port, different than the input port, configured to receive a common mode leakage signal associated with the oscillating signal.

2. The wireless circuitry of claim 1, further comprising:
a transformer having a first coil coupled to the radio-frequency amplifier and having a second coil coupled to the mixer.

3. The wireless circuitry of claim 2, further comprising:
a first capacitor coupled between a first output or input terminal of the radio-frequency amplifier and the input port of the power detection circuit; and
a second capacitor coupled between a second output or input terminal of the radio-frequency amplifier and the input port of the power detection circuit.

4. The wireless circuitry of claim 3, further comprising:
a third capacitor coupled between the first capacitor and the common mode cancellation input port of the power detection circuit; and
a fourth capacitor coupled between the second capacitor and the common mode cancellation input port of the power detection circuit.

5. The wireless circuitry of claim 3, further comprising:
a third capacitor coupled between a first terminal of the second coil and the common mode cancellation input port of the power detection circuit; and
a fourth capacitor coupled between a second terminal of the second coil and the common mode cancellation input port of the power detection circuit.

6. The wireless circuitry of claim 3, further comprising:
a third capacitor coupled between a center tap of the second coil and the common mode cancellation input port of the power detection circuit.

7. The wireless circuitry of claim 6, wherein the third capacitor has an adjustable capacitance that is trimmed to cancel out a common mode leakage signal received at the input port of the power detection circuit.

8. The wireless circuitry of claim 6, wherein the third capacitor has an adjustable capacitance that is trimmed to only partially cancel out a common mode leakage signal received at the input port of the power detection circuit.

9. The wireless circuitry of claim 3, further comprising:
a resistor coupled between a center tap of the second coil and the common mode cancellation input port of the power detection circuit, wherein the resistor has an adjustable resistance that is trimmed to fully cancel out or only partially cancel out a common mode leakage signal received at the input port of the power detection circuit.

10. The wireless circuitry of claim 1, wherein the power detection circuit comprises:
a first input transistor having a gate terminal coupled to the input port of the power detection circuit;
a second input transistor having a gate terminal coupled to the input port of the power detection circuit;
a replica input transistor;
a first load transistor coupled in series with the first and second input transistors;
a second load transistor coupled in series with the replica input transistor.

11. The wireless circuitry of claim 10, wherein the replica input transistor has a gate terminal coupled to the common mode cancellation input port of the power detection circuit.

12. The wireless circuitry of claim 11, wherein the first input transistor has a first transistor size, wherein the second input transistor has a second transistor size equal to the first transistor size, and wherein the replica input transistor has a third transistor size greater than the first transistor size.

13. Circuitry comprising:
a radio-frequency amplifier; and
a power detection circuit coupled to an output or input port of the radio-frequency amplifier, wherein the power detection circuit includes
a first input transistor coupled to the output or input port of the radio-frequency amplifier,
a second input transistor coupled to the output or input port of the radio-frequency amplifier, and
a replica input transistor coupled to a common mode cancellation input port of the power detection circuit.

14. The circuitry of claim 13, further comprising:
a mixer coupled to the radio-frequency amplifier and configured to receive a local oscillator (LO) signal, wherein the common mode cancellation input port is configured to receive a common mode leakage signal associated with the LO signal.

15. The circuitry of claim 13, wherein the power detection circuit further comprises:
a first load transistor coupled in series with the first and second input transistors; and
a second load transistor coupled in series with the replica input transistor.

16. The circuitry of claim 13, further comprising:
a transformer coupled to the output or input port of the radio-frequency amplifier; and
one or more capacitors coupled between the transformer and the common mode cancellation input port of the power detection circuit.

17. The circuitry of claim 16, wherein the one or more capacitors comprises an adjustable capacitor or an adjustable resistor that is trimmed to fully cancel out or only partially cancel out a common mode leakage signal received at the first and second input transistors.

18. The circuitry of claim 17, wherein the transformer includes a primary coil and a secondary coil, and wherein the adjustable capacitor is coupled to a center tap terminal of the secondary coil in the transformer.

19. Circuitry comprising:
a passive circuit;
a transformer having a first coil coupled to the passive circuit and having a second coil; and
a power detector having a differential input port coupled to the first coil of the transformer and having a common mode cancellation input port, separate from the differential input port, coupled to a center tap of the first coil of the transformer.

20. The circuitry of claim 19, wherein the power detector comprises:
a first input transistor having a gate terminal coupled to the differential input port of the power detector;
a second input transistor having a gate terminal coupled to the differential input port of the power detector; and
a third input transistor having a gate terminal coupled to the common mode cancellation input port of the power detector.
